(19) United States
(12) Patent Application Publication
(10) Pub. No.: US 2016/0240155 A1
(43) Pub. Date: Aug. 18, 2016

(54) AMPLIFIER CIRCUIT APPLIED IN SOURCE DRIVER OF LIQUID CRYSTAL DISPLAY

(71) Applicant: Raydium Semiconductor Corporation, Hsinchu (TW)

(72) Inventors: Yung-Hsiang YANG, Hsinchu City (TW); Po-Cheng LIN, Hsinchu City (TW)

(21) Appl. No.: 15/013,342

(22) Filed: Feb. 2, 2016

Related U.S. Application Data
(60) Provisional application No. 62/115,328, filed on Feb. 12, 2015.

(51) Int. Cl. G09G 3/36; H03F 1/02; H03F 3/45

(52) U.S. Cl. CPC G09G 3/3648; H03F 3/45179; H03F 1/0205; H03F 2200/471; H03F 2203/45074; G09G 2300/0426; G09G 2310/0291; G09G 2330/021; G09G 2310/08

(57) ABSTRACT

An amplifier circuit applied in a source driver of a liquid crystal display includes a differential input stage, a first output stage, a second output stage, and a detection module. The differential input stage receives a positive input voltage and a negative input voltage. The first output stage is coupled between a first voltage and a second voltage smaller than first voltage. A first transistor and a second transistor of first output stage are coupled to differential input stage. The second output stage is coupled between second voltage and a third voltage smaller than second voltage. A third transistor and a fourth transistor of second output stage are coupled to differential input stage. The detection module detects whether positive input voltage is larger than a reference voltage and selectively switch-on first output stage and switch-off second output stage or switch-on second output stage and switch-off first output stage.

### BACKGROUND OF THE INVENTION

1. Field of the Invention

This invention relates to an amplifier circuit, especially to an amplifier circuit applied in a source driver of a liquid crystal display.

2. Description of the Related Art

Please refer to FIG. 1. FIG. 1 illustrates a schematic diagram of a conventional amplifier circuit applied in a source driver of a liquid crystal display. As shown in FIG. 1, the conventional amplifier circuit 1 applied in the source driver of the liquid crystal display includes an operational amplifier OP1 and an output stage OS. The output stage OS includes transistors M1 and M2 having high driving capability. A negative input terminal − of the operational amplifier OP1 receives a first input voltage INN and a positive input terminal + of the operational amplifier OP1 receives a second input voltage INP.

It is assumed that an output voltage of the amplifier circuit 1 is VO and an output current of the amplifier circuit 1 is IO, a current flowing through the transistor M1 is I1 and a voltage across the transistor M1 is V1, and a current flowing through the transistor M2 is I2 and a voltage across the transistor M2 is V2. Since the power consumption P_{M1} of the transistor M1 equals to (I1*V1) and I1=IO+I2 and V1=SUP1−VO; therefore, P_{M1}=(IO+I2)*(SUP1−VO). As to the power consumption P_{M2} of the transistor M2, P_{M2}=(I2*V2)=I2*(VO−VSN1)=I2*VO.

When the output current IO of the amplifier circuit 1 is large, the current I1 flowing through the transistor M1 also becomes large, and the power consumption P_{M1} of the transistor M1 will also becomes large accordingly; therefore, the temperature and the power consumption of the amplifier circuit 1 will be largely increased accordingly. In practical applications, the temperature may be increased even 20 degrees.

### SUMMARY OF THE INVENTION

Therefore, the invention provides an amplifier circuit applied in a source driver of a liquid crystal display to solve the above-mentioned problems.

A preferred embodiment of the invention is an amplifier circuit applied in a source driver of a liquid crystal display. In this embodiment, the amplifier circuit includes a differential input stage, a first output stage, a second output stage, and a detection module. The differential input stage is configured to receive a positive input voltage and a negative input voltage respectively.

The first output stage is coupled between a first voltage and a second voltage smaller than the first voltage. The first output stage includes a first transistor and a second transistor coupled to the differential input stage respectively.

The second output stage is coupled between the second voltage and a third voltage smaller than the second voltage. The second output stage includes a third transistor and a fourth transistor coupled to the differential input stage respectively.

The detection module is coupled to the positive input voltage, the first output stage and the second output stage respectively. The detection module is configured to detect whether the positive input voltage is smaller than a reference voltage and selectively switch the first output stage on and switch the second output stage off or switch the second output stage on and switch the first output stage off according to a detection result of the detection module.

In an embodiment, if the detection result of the detection module is yes, the detection module outputs a control signal to switch the second output stage on and switch the first output stage off; if the detection result of the detection module is no, the detection module outputs the control signal to switch the first output stage on and switch the second output stage off.

In an embodiment, the differential input stage is an operational amplifier, a positive input terminal and a negative input terminal of the operational amplifier receive the positive input voltage and the negative input voltage respectively; a first output terminal of the operational amplifier is coupled to the first transistor of the first output stage and the third transistor of the second output stage respectively and a second output terminal of the operational amplifier is coupled to the second transistor of the first output stage and the fourth transistor of the second output stage respectively.

In an embodiment, the first output terminal of the operational amplifier is coupled to a gate electrode of the first transistor of the first output stage through a first switch; the second output terminal of the operational amplifier is coupled to a gate electrode of the second transistor of the first output stage through a second switch; the first output terminal of the operational amplifier is coupled to a gate electrode of the third transistor of the second output stage through a third switch; the second output terminal of the operational amplifier is coupled to a gate electrode of the fourth transistor of the second output stage through a fourth switch.

In an embodiment, the first transistor and the second transistor are a P-type transistor and an N-type transistor respectively.

In an embodiment, the third transistor and the fourth transistor are a P-type transistor and an N-type transistor respectively.

In an embodiment, the detection module includes a comparator, and the comparator compares the positive input voltage with the reference voltage and then outputs the control signal according to a comparison result of the comparator.

In an embodiment, the detection module includes a comparator and a timer, and the comparator compares the positive input voltage with the reference voltage and then outputs the control signal to the timer according to a comparison result of the comparator; if a maintaining time of the comparison result is longer than a default time calculated by the timer, the timer outputs the control signal.

In an embodiment, the detection module includes a comparator and a delay unit, the delay unit at least includes a resistor and a capacitor, and the comparator compares the positive input voltage with the reference voltage and then outputs the control signal to the delay unit according to a comparison result of the comparator; if a maintaining time of the comparison result is longer than a delay time formed by the resistor and the capacitor of the delay unit, the delay unit outputs the control signal.

In an embodiment, the detection module further includes a Schmitt trigger coupled to the delay unit, and the Schmitt trigger is configured to stabilize the delay time formed by the resistor and the capacitor and reduce noise interferences.

In an embodiment, the reference voltage equals to the second voltage.

Compared to the prior art, the amplifier circuit applied in the source driver of the liquid crystal display disclosed in the invention can effectively achieve the following effects:

(1) Because the first output stage and the second output stage are switched to operate by the detection module in the invention, the power consumption of the output stages can be effectively reduced and the temperature of the amplifier circuit can be also largely decreased to achieve the effects of saving power and enhancing the market competitiveness of the amplifier circuit.

(2) Because the output stages of the amplifier circuit in the invention are operated under a smaller voltage range between the first voltage and the second voltage or between the second voltage and the ground voltage instead of being operated under a larger voltage range between the first voltage and the ground voltage, the transistors having smaller withstand voltage (e.g., half-voltage) can be used to form the output stages to reduce the IC size and manufacturing cost of the amplifier circuit.

The advantage and spirit of the invention may be understood by the following detailed descriptions together with the appended drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic diagram of a conventional amplifier circuit applied in a source driver of a liquid crystal display.

FIG. 2 illustrates a schematic diagram of an amplifier circuit applied in a source driver of a liquid crystal display in a preferred embodiment of the invention.

FIG. 3 illustrates a schematic diagram of the operation of the amplifier circuit when the positive input voltage is smaller than the reference voltage.

FIG. 4-FIG. 7 illustrate different embodiments of the detection module of the amplifier circuit respectively.

### DETAILED DESCRIPTION

A preferred embodiment of the invention is an amplifier circuit. In this embodiment, the amplifier circuit is applied in a source driver of a liquid crystal display, but not limited to this.

Please refer FIG. 2. FIG. 2 illustrates a schematic diagram of an amplifier circuit applied in a source driver of a liquid crystal display in a preferred embodiment of the invention.

As shown in FIG. 2, the amplifier circuit 2 includes a differential input stage OP1, a first output stage OS1, a second output stage OS2 and a detection module 20. In fact, the differential input stage OP1 can be an operational amplifier, but not limited to this. The differential input stage OP1 is coupled to the first output stage OS1 and the second output stage OS2 respectively; a positive input terminal + and a negative input terminal − of the differential input stage OP1 receive a positive input voltage INP and a negative input voltage INN respectively; the first output stage OS1 and the second output stage OS2 are coupled in series and the output terminals of the first output stage OS1 and the second output stage OS2 are both coupled to an output voltage VO; the first output stage OS1 is coupled between a first voltage SUP1 and a second voltage SUP2; the second output stage OS2 is coupled between a second voltage SUP2 and a third voltage VSN1; the detection module 20 is coupled to the positive input voltage INP, a reference voltage VREF, the first output stage OS1 and the second output stage OS2 respectively.

In an embodiment of the invention, if the output voltage VO is coupled to the negative input terminal − of the differential input stage OP1, that is to say, the output voltage VO is used as the negative input voltage INN, then a buffer will be formed. Under the effect that the amplifier circuit 2 forms imaginary short, the output voltage VO will be similar or equal to the positive input voltage INP received by the positive input terminal + of the differential input stage OP1.

In fact, when the amplifier circuit 2 is used as the buffer in the liquid crystal display, the buffer can drive equivalent multi-level RC series loads of the liquid crystals on the LCD panel to push the resistive load, but not limited to this.

As to the first output stage OS1, the first output stage OS1 includes a first transistor M1 and a second transistor M2. The first transistor M1 and the second transistor M2 are coupled in series between the first voltage SUP1 and the second voltage SUP2, wherein the first voltage SUP1 is larger than the second voltage SUP2. A node between the first transistor M1 and the second transistor M2 is coupled to the output voltage VO; a gate electrode of the first transistor M1 is coupled to the first output terminal of the differential input stage OP1 through a first switch; a gate electrode of the second transistor M2 is coupled to the second output terminal of the differential input stage OP1 through a second switch. In fact, the first transistor M1 and the second transistor M2 of the first output stage OS1 can be P-type transistor and N-type transistor respectively, but not limited to this.

Similarly, as to the second output stage OS2, the second output stage OS2 includes a third transistor M3 and a fourth transistor M4. The third transistor M3 and the fourth transistor M4 are coupled in series between the second voltage SUP2 and the third voltage VSN1, wherein the second voltage SUP2 is larger than the third voltage VSN1. A node between the third transistor M3 and the fourth transistor M4 is coupled to the output voltage VO; a gate electrode of the third transistor M3 is coupled to the first output terminal of the differential input stage OP1 through a third switch; a gate electrode of the fourth transistor M4 is coupled to the second output terminal of the differential input stage OP1 through a fourth switch.

In fact, the third voltage VSN1 can be a positive voltage, a ground voltage or a negative voltage smaller than the second voltage SUP2 without any specific limitations. The third transistor M3 and the fourth transistor M4 of the second output stage OS2 can be P-type transistor and N-type transistor respectively, but not limited to this.

In this embodiment, the detection module 20 is configured to detect whether the positive input voltage INP is smaller than the reference voltage VREF and selectively switch the first output stage OS1 on and switch the second output stage OS2 off, or switch the second output stage OS2 on and switch the first output stage OS1 off according to a detection result of the detection module 20. In other words, the first output stage OS1 and the second output stage OS2 will not be switched on at the same time; at one time, only one of the first output stage OS1 and the second output stage OS2 is switched on and the other of them is switched off.

In an embodiment, the reference voltage VREF can be equal to the second voltage SUP2; if the detection result of the detection module 20 is yes, that is to say, the positive input voltage INP is smaller than the reference voltage VREF (the second voltage SUP2), the detection module 20 will output a control signal VCTRL having low-level to switch the second output stage OS2 on and switch the first output stage OS1 off.

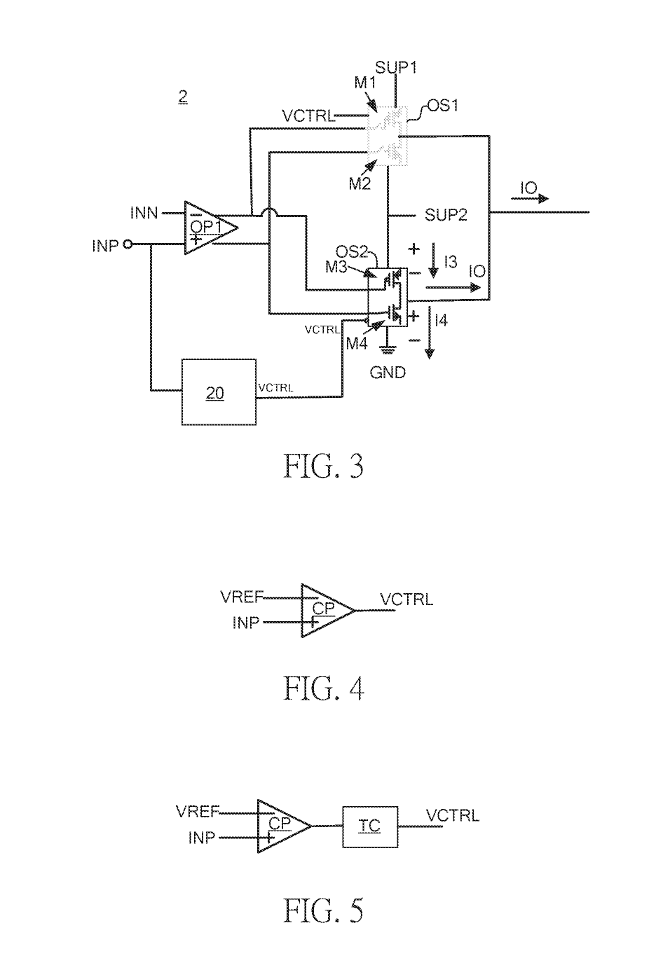

Please refer to FIG. 3. FIG. 3 illustrates a schematic diagram of the operation of the amplifier circuit 2 when the positive input voltage INP is smaller than the reference voltage VREF. As shown in FIG. 3, the detection module 20 switches the third transistor M3 and the fourth transistor M4 of the second output stage OS2 on and switches the first transistor M1 and the second transistor M2 of the first output stage OS1 off.

Therefore, the output stages of the amplifier circuit 2 can be only operated under a voltage range between the second voltage SUP2 and the third voltage VSN1. Since this voltage range between the second voltage SUP2 and the third voltage VSN1 is smaller than the voltage range between the first voltage SUP1 and the third voltage VSN1 that the amplifier circuit 1 of the prior art is operated, it is believed that the power consumption of the output stages can be reduced and the transistors having smaller withstand voltage can be used to form the output stages to save costs.

In practical applications, it is assumed that the first voltage SUP1 and the second voltage SUP2 are 10 volts and 5 volts respectively; the third voltage VSN1 is 0 volt; the positive input voltage INP and the output voltage VO are 4 volts; the output current IO is 10 mA; the current I2 flowing through the second transistor M2 and the current I4 flowing through the fourth transistor M4 are 1 uA.

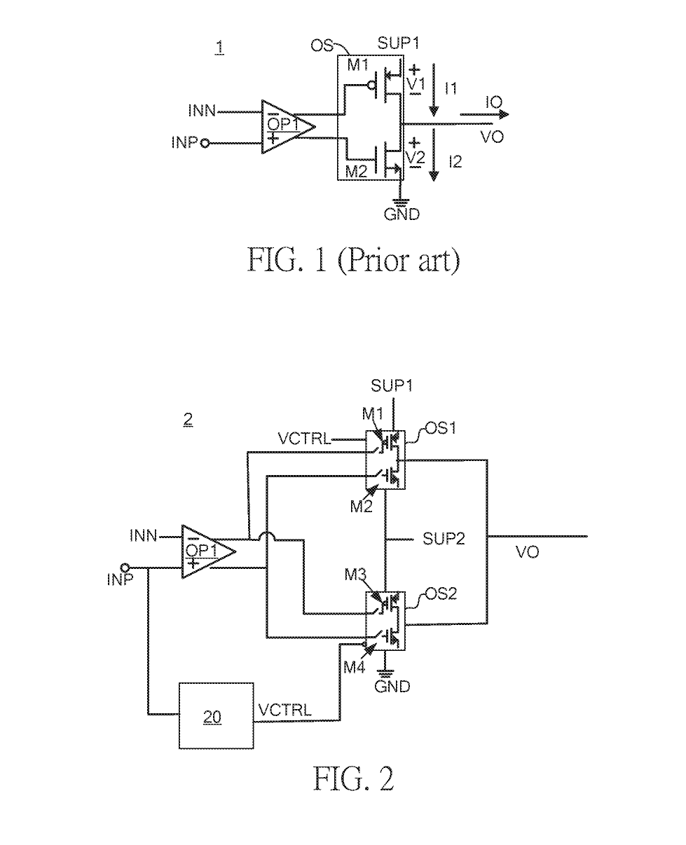

In the amplifier circuit 1 of the prior art shown in FIG. 1, the power consumption P_{M1} of the operated first transistor M1 equals to (10V−4V)*(10 mA+1 uA)=0.06 W and the power consumption P_{M2} of the operated second transistor M2 equals to (4V)*(1 uA)=4 uW; in the amplifier circuit 2 of the invention shown in FIG. 3, the power consumption P_{M3} of the operated third transistor M3 equals to (5V−4V)*(10 mA+1 uA)=0.01 W and the power consumption P_{M4} of the operated fourth transistor M4 equals to (4V)*(1 uA)=4 uW.

From the above-mentioned comparison, it is obvious that the power consumption P_{M3} of the operated third transistor M3 in the invention is smaller than the power consumption P_{M1} of the operated first transistor M1 in the prior art; as a result, the power consumption of the output stages when the amplifier circuit 2 of the invention is operated is 0.05 W smaller than that when the amplifier circuit 1 of the prior art is operated. Since the power consumption of the output stages can be reduced by as much as 84%, it is believed that the amplifier circuit 2 of the invention can achieve very good effect of reducing power consumption.

On the other hand, if the detection result of the detection module 20 is no, that is to say, the positive input voltage INP is not smaller than the reference voltage VREF (the second voltage SUP2), the detection module 20 will output a control signal VCTRL having high-level to switch the first output stage OS1 on and switch the second output stage OS2 off.

At this time, the output stages of the amplifier circuit 2 can be only operated under a voltage range between the first voltage SUP1 and the second voltage VUP2. Since this voltage range between the first voltage SUP1 and the second voltage VUP2 is smaller than the voltage range between the first voltage SUP1 and the third voltage VSN1 that the amplifier circuit 1 of the prior art is operated, it is believed that the power consumption of the output stages can be reduced and the transistors having smaller withstand voltage can be used to form the output stages to save costs.

In another embodiment, if the detection result of the detection module 20 is yes, that is to say, the positive input voltage INP is smaller than the reference voltage VREF (the second voltage SUP2), the detection module 20 will output a control signal VCTRL having high-level to switch the first output stage OS1 on and switch the second output stage OS2 off; if the detection result of the detection module 20 is no, that is to say, the positive input voltage INP is not smaller than the reference voltage VREF (the second voltage SUP2), the detection module 20 will output a control signal VCTRL having low-level to switch the second output stage OS2 on and switch the first output stage OS1 on.

Above all, it can be found that the first output stage OS1 and the second output stage OS2 of the amplifier circuit 2 will not be switched on at the same time; at one time, only one of the first output stage OS1 and the second output stage OS2 is switched on and the other of them is switched off. Therefore, the output stages of the amplifier circuit 2 can be only operated under a smaller voltage range to reduce power consumption of the output stages and transistors having smaller withstand voltage can be used to form the output stages to reduce costs.

Then, please refer to FIG. 4-FIG. 7. FIG. 4-FIG. 7 illustrate different embodiments of the detection module 20 of the amplifier circuit 2 respectively.

As shown in FIG. 4, the detection module 20 can include a comparator CP. When a positive input terminal + and a negative input terminal − of the comparator CP receive the positive input voltage INP and the reference voltage VREF respectively, the comparator CP will compare the positive input voltage INP with the reference voltage VREF and then selectively outputs the control signal VCTRL having high-level or low-level to the first output stage OS1 and the second output stage OS2 according to a comparison result of the comparator CP to control the first output stage OS1 and the second output stage OS2.

For example, it is assumed that the reference voltage VREF is 5 volts, if the positive input voltage INP received by the positive input terminal + of the comparator CP is larger than 5 volts, the comparator CP will output the control signal VCTRL having high-level to switch the first output stage OS1 on and switch the second output stage OS2 off; if the positive input voltage INP received by the positive input terminal + of the comparator CP is smaller than 5 volts, the comparator CP will output the control signal VCTRL having low-level to switch the second output stage OS2 on and switch the first output stage OS1 off.

As shown in FIG. 5, the detection module 20 can include a comparator CP and a timer TC. When the comparator CP receive the positive input voltage INP and the reference voltage VREF respectively, the comparator CP will compare the positive input voltage INP with the reference voltage VREF and then generate the control signal VCTRL having high-level or low-level to the timer TC according to a comparison result of the comparator CP.

In this embodiment, the main function of the timer TC is to calculate a default delay time as a digital form determination mechanism to protect the positive input voltage INP with the reference voltage VREF from being interfered by noises; therefore, the first output stage OS1 and the second output stage OS2 will not be malfunctioned to reduce unnecessary power consumption of the output stages.

For example, if a maintaining time of the comparison result of the comparator CP (e.g., the positive input voltage INP is larger than 5 volts) is longer than a default time calculated by the timer TC, then the timer TC will output the control signal VCTRL having high-level to switch the first output stage OS1 on and switch the second output stage OS2 off.

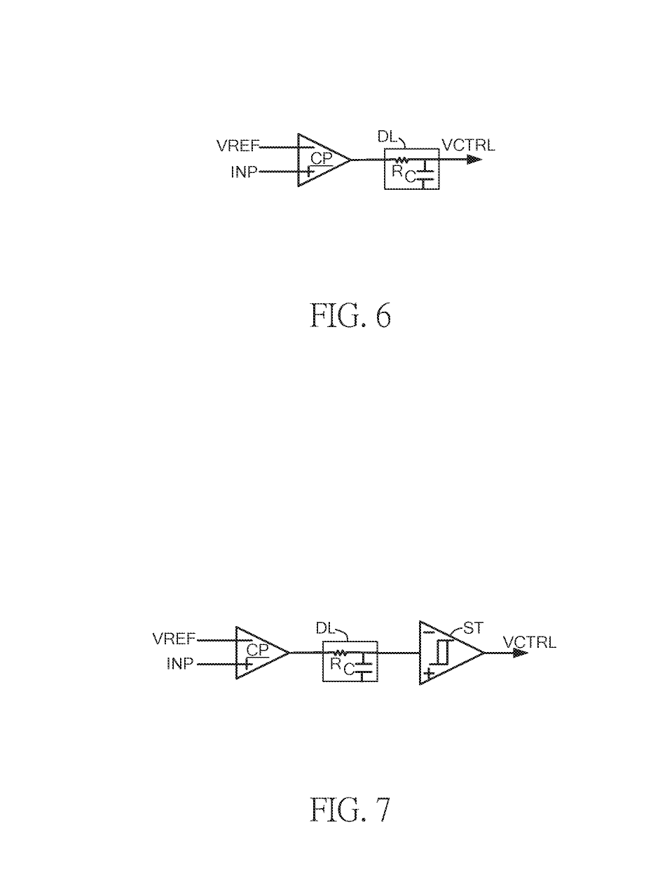

As shown in FIG. 6, the detection module 20 can include a comparator CP and a delay unit DL. When the comparator CP receive the positive input voltage INP and the reference voltage VREF respectively, the comparator CP will compare the positive input voltage INP with the reference voltage VREF and then generate the control signal VCTRL having high-level or low-level to the delay unit DL according to a comparison result of the comparator CP.

In this embodiment, the delay unit DL at least includes a resistor R and a capacitor C. The main function of the delay unit DL is to provide a RC delay time to be an analog-type determination mechanism.

For example, if a maintaining time of the comparison result (e.g., the positive input voltage INP is larger than 5 volts) is longer than a RC delay time formed by the resistor R and the capacitor C of the delay unit DL, then the delay unit DL will output the control signal VCTRL having high-level to switch the first output stage OS1 on and switch the second output stage OS2 off.

As shown in FIG. 7, the detection module 20 can further include a Schmitt trigger ST coupled to the delay unit DL. It should be noticed that the Schmitt trigger ST is configured to stabilize the RC delay time formed by the resistor R and the capacitor C of the delay unit DL and also reduce noise interferences.

Compared to the prior art, the amplifier circuit applied in the source driver of the liquid crystal display disclosed in the invention can effectively achieve the following effects:

(1) Because the first output stage and the second output stage are switched to operate by the detection module in the invention, the power consumption of the output stages can be effectively reduced and the temperature of the amplifier circuit can be also largely decreased to achieve the effects of saving power and enhancing the market competitiveness of the amplifier circuit.

(2) Because the output stages of the amplifier circuit in the invention are operated under a smaller voltage range between the first voltage and the second voltage or between the second voltage and the ground voltage instead of being operated under a larger voltage range between the first voltage and the ground voltage, transistors having smaller withstand voltage (e.g., half-voltage) can be used to form the output stages to reduce the IC size and manufacturing cost of the amplifier circuit.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. An amplifier circuit applied in a source driver of a liquid crystal display, the amplifier circuit comprising:
a differential input stage configured to receive a positive input voltage and a negative input voltage respectively;
a first output stage coupled between a first voltage and a second voltage, the first output stage comprising a first transistor and a second transistor coupled to the differential input stage respectively, wherein the second voltage is smaller than the first voltage;
a second output stage coupled between the second voltage and a third voltage, the second output stage comprising a third transistor and a fourth transistor coupled to the differential input stage respectively, wherein the third voltage is smaller than the second voltage; and
a detection module coupled to the positive input voltage, the first output stage and the second output stage respectively, the detection module being configured to detect whether the positive input voltage is smaller than a reference voltage and selectively switch the first output stage on and switch the second output stage off or switch the second output stage on and switch the first output stage off according to a detection result of the detection module.

2. The amplifier circuit of claim 1, wherein if the detection result of the detection module is yes, the detection module outputs a control signal to switch the second output stage on and switch the first output stage off; if the detection result of the detection module is no, the detection module outputs the control signal to switch the first output stage on and switch the second output stage off.

3. The amplifier circuit of claim 1, wherein the differential input stage is an operational amplifier, a positive input terminal and a negative input terminal of the operational amplifier receive the positive input voltage and the negative input voltage respectively; a first output terminal of the operational amplifier is coupled to the first transistor of the first output stage and the third transistor of the second output stage respectively and a second output terminal of the operational amplifier is coupled to the second transistor of the first output stage and the fourth transistor of the second output stage respectively.

4. The amplifier circuit of claim 3, wherein the first output terminal of the operational amplifier is coupled to a gate electrode of the first transistor of the first output stage through a first switch; the second output terminal of the operational amplifier is coupled to a gate electrode of the second transistor of the first output stage through a second switch; the first output terminal of the operational amplifier is coupled to a gate electrode of the third transistor of the second output stage through a third switch; the second output terminal of the operational amplifier is coupled to a gate electrode of the fourth transistor of the second output stage through a fourth switch.

5. The amplifier circuit of claim 1, wherein the first transistor and the second transistor are a P-type transistor and an N-type transistor respectively.

6. The amplifier circuit of claim 1, wherein the third transistor and the fourth transistor are a P-type transistor and an N-type transistor respectively.

7. The amplifier circuit of claim 2, wherein the detection module comprises a comparator; and the comparator compares the positive input voltage with the reference voltage and then outputs the control signal according to a comparison result of the comparator.

8. The amplifier circuit of claim 2, wherein the detection module comprises a comparator and a timer, and the comparator compares the positive input voltage with the reference voltage and then outputs the control signal to the timer according to a comparison result of the comparator; if a maintaining time of the comparison result is longer than a default time calculated by the timer, the timer outputs the control signal.

9. The amplifier circuit of claim 2, wherein the detection module comprises a comparator and a delay unit, the delay unit at least comprises a resistor and a capacitor, and the comparator compares the positive input voltage with the reference voltage and then outputs the control signal to the delay unit according to a comparison result of the comparator; if a maintaining time of the comparison result is longer than a delay time formed by the resistor and the capacitor of the delay unit, the delay unit outputs the control signal.

10. The amplifier circuit of claim 9, wherein the detection module further comprises a Schmitt trigger coupled to the delay unit, and the Schmitt trigger is configured to stabilize the delay time formed by the resistor and the capacitor and reduce noise interferences.

11. The amplifier circuit of claim 1, wherein the reference voltage equals to the second voltage.
